(19) United States
(12) Patent Application Publication
(10) Pub. No.: US 2002/0145192 A1
(43) Pub. Date: Oct. 10, 2002

(54) Heat-resisting high-power diode

(76) Inventor: Chin-Feng Lin, Taipei Hsien (TW)

Correspondence Address: DOUGHERTY & TROXELL, Suite 1404, 5205 Leesburg Pike, Falls Church, VA, 22041, US

(21) Appl. No.: 09/827,144

(22) Filed: Apr. 6, 2001

(51) Int. Cl. H01L 23/22; H01L 23/24; H01L 23/34

(52) U.S. Cl. 257/687; 257/727; 257/728; 257/730; 257/731

(57) ABSTRACT

A heat-resisting high-power diode includes a casing defining a receiving chamber, a chip unit mounted in the receiving chamber and soldered to the casing by tin solder, a conductor unit soldered to the chip unit by tin solder, a cover shell riveted to the casing to close the receiving chamber, and a jelly-like electrically insulative glue of specific gravity lower than tin solder filled in the receiving chamber and covered over the chip unit and the lower part of the conductor unit to prohibit tin solder from flowing out of the casing when melted due to an excessively high working temperature.

### BACKGROUND OF THE INVENTION

The present invention relates to a diode and, more particularly, to a heat-resisting high-power diode, which is practical for use under a 300° C. high working temperature.

FIG. 1 shows a high-power diode according to the prior art. This structure of high-power diode comprises a casing 1′ defining a receiving chamber 11′, a chip unit 2′ mounted in the receiving chamber 11′, a conductor unit 3′, and a cover shell 4′. The chip unit 2′ is supported between the casing 1′ and the conductor unit 3′, having a bottom soldering face 5′ and a top soldering face 6′ respectively soldered to the casing 1′ and the conductor unit 3′ by a tin soldering process. The conductor unit 3′ comprises a lead rod 32′ and a soldering block 31′ connected to the bottom end of the lead rod 32′ and soldered to the chip unit 2′. The cover shell 4′ is covered on the casing 1′ to close the receiving chamber 11′. The bottom surface of the cover shell 4′ is soldered to the top surface of the soldering block 31′ of the conductor unit 3′. The periphery 7′ of the cover shell 4′ is soldered to the rim 12′ of the casing 1′. The maximum working temperature of this structure of high-power diode is about 175-200° C. Because tin solder is used to connect the component parts of this structure of high-power diode one another, it starts to melt when the working temperature surpassed the set working range of 175-200° C. In this case, the chip unit 2′ will be disconnected from the conductor unit 3′ to open the circuit, and melted tin solder will flow out of the casing 1′ to short-circuit the external circuit.

### SUMMARY OF THE INVENTION

The present invention has been accomplished to provide a heat-resisting high-power diode, which is practical for use under the working temperature below 300° C. According to one aspect of the present invention, the cover shell is fastened to the casing by a rivet joint, and a jelly-like electrically insulative glue is filled in the casing and covered over the chip unit and the soldering block of the conductor unit to prohibit tin solder from flowing out of the casing when melted due to an excessively high temperature. According to another aspect of the present invention, the jelly-like electrically insulative glue shows a solid-liquid state and penetrates through the capillary of the periphery of the chip unit when at a high temperature, preventing the chip unit from cracking.

### BRIEF DESCRIPTION OF THE DRAWINGS

FIG. 1 is a sectional view of a high-power diode constructed according to the prior art.

FIG. 2 is an elevational view of a diode constructed according to the present invention.

FIG. 3 is an exploded view of the diode shown in FIG. 2.

FIG. 4 is a side plain view of the diode shown in FIG. 2.

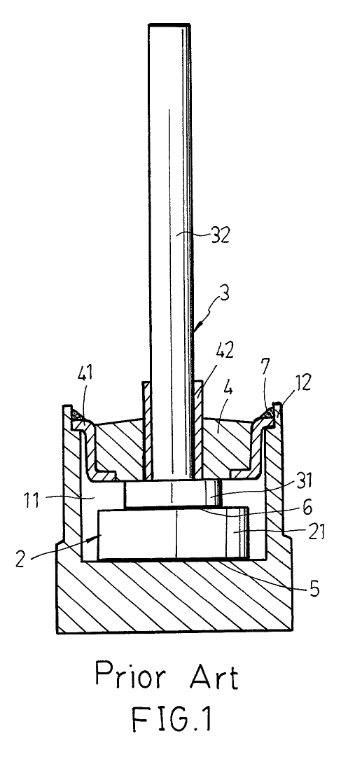

### DETAILED DESCRIPTION OF THE PREFERRED EMBODIMENT

Referring to FIGS. from 2 through 4, a heat-resisting high-power diode is shown comprised of a hollow, cylindrical, top-open casing 1, a chip unit 2, a conductor unit 3, and a cover shell 4. The chip unit 2, the conductor unit 3 and the cover shell 4 are mounted in the receiving chamber 11 of the casing 1. The chip unit 2 is supported between the casing 1 and the conductor unit 3, having a bottom soldering face 5 and a top soldering face 6 respectively soldered to the casing 1 and the conductor unit 3 by tin solder. The conductor unit 3 comprises a lead rod 32 and a soldering block 31 connected to the bottom end of the lead rod 32 and soldered to the top soldering surface 6 of the chip unit 2. The cover shell 4 is covered on the casing 1 to close the receiving chamber 11, having a center tube 42 through which the lead rod 32 of the conductor unit 3 extends to the outside for connection to an external circuit. A jelly-like electrically insulative glue 8 is filled in the receiving chamber 11 of the casing 1 before closing the cover shell 4, keeping the chip unit 2 and the soldering block 31 of the conductor unit 3 embedded in the jelly-like electrically insulative glue 8. The jelly-like electrically insulative glue 8 has a specific gravity lower than tin solder, forming a protection layer. In case the working temperature surpassed the set critical range and the tin solder starts to melt, molten tin solder is kept beneath the jelly-like electrically insulative glue 8 and prohibited from flowing out of the casing 1.

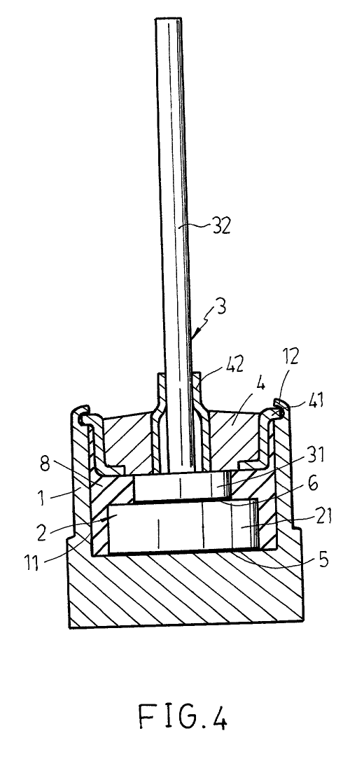

Referring to FIGS. 3 and 4 again, the casing 1 comprises a top coupling flange 12 peripherally upwardly extended from the rim thereof adapted to receive the cover shell 4. The cover shell 4 comprises an outward coupling flange 41 extended from the periphery and fitted into the space defined within the top coupling flange 12. After installation of the cover shell 4, the top coupling flange 12 of the casing 1 is hammered down to fixedly secure the outward coupling flange 41 of the cover shell 4 in position, and the top end of the center tube 42 is radially inwardly compressed and deformed to fixedly secure the lead rod 32 of the conductor unit 3 in position.

As indicated above, the cover shell 4 is riveted to the casing 1 to hold down the soldering block 31 of the conductor unit 3 and the chip unit 2 in the jelly-like electrically insulative glue 8 inside the casing 1. When the tin solder starts to melt due to an excessively high working temperature, molten tin solder is constantly maintained beneath the jelly-like electrically insulative glue 8 and prohibited from flowing out of the casing 1, and therefore the connection between the chip unit 2 and the conductor unit 3 is well maintained. Further, the jelly-like electrically insulative glue 8 shows a solid-liquid state at a high temperature, and will penetrate through capillary of the rubber periphery 21 of the chip unit 2, preventing the chip unit 2 from cracking.

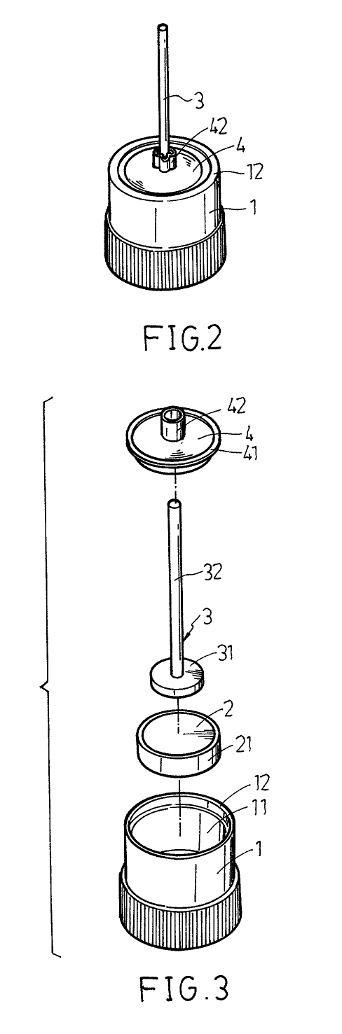

A prototype of heat-resisting high-power diode has been constructed with the features of FIGS. 2-4. The heat-resisting high-power diode functions smoothly to provide all of the features discussed earlier.

Although a particular embodiment of the invention has been described in detail for purposes of illustration, various modifications and enhancements may be made without departing from the spirit and scope of the invention. Accordingly, the invention is not to be limited except as by the appended claims.

What the invention claimed is:

1. A heat-resisting high-power diode comprising a hollow, cylindrical, top-open casing defining a receiving chamber, a chip unit mounted in said receiving chamber, said chip unit having a bottom soldering surface soldered to said casing by tin solder and a top soldering surface, a conductor unit mounted in said receiving chamber, said conductor unit comprising a soldering block soldered to the top soldering surface of said chip and a lead rod upwardly extended from said soldering block to the outside of said casing, and a cover shell covered on said receiving chamber to hold down said soldering block of said conductor unit and said chip unit, wherein a jelly-like electrically insulative glue of specific gravity lower than tin solder is filled in said receiving chamber of said casing before closing said cover shell, keeping the soldering block of said conductor unit and said chip unit embedded in said jelly-like electrically insulative glue; said cover shell comprises an outward coupling flange coupled to said casing; said casing comprises a top coupling flange riveted to the outward coupling flange of said cover shell to fixedly secure said cover shell to said casing.

2. The heat-resisting high-power diode of claim 1 wherein said jelly-like electrically insulative glue shows a solid-liquid state to penetrate capillary in the periphery of said chip unit when at a high temperature, preventing said chip unit from cracking.
